(19) United States
(12) Patent Application Publication
(10) Pub. No.: US 2026/0101680 A1
(43) Pub. Date: Apr. 9, 2026

(54) CMOS-COMPATIBLE RESISTIVE RANDOM-ACCESS MEMORY (RRAM) DEVICES

(71) Applicant: TetraMem Inc., Fremont, CA (US)

(72) Inventors: Minxian Zhang, Amherst, MA (US); Mingche Wu, San Jose, CA (US); Gary Miner, Fremont, CA (US); Yuan Dao, Fremont, CA (US); Ning Ge, Danville, CA (US)

(73) Assignee: TetraMem Inc., Fremont, CA (US)

(21) Appl. No.: 18/906,147

(22) Filed: Oct. 3, 2024

(51) Int. Cl. H10N 70/00; H10B 63/00

(52) U.S. Cl. CPC H10N 70/8833; H10B 63/30; H10B 63/80; H10N 70/023; H10N 70/026; H10N 70/063; H10N 70/066; H10N 70/068; H10N 70/841

(57) ABSTRACT

An apparatus including a CMOS-compatible resistive random-access memory (RRAM) device is provided. An RRAM device may include a bottom electrode, a switching oxide device comprising at least one transition metal oxide, a via structure fabricated on the switching oxide device, and a top electrode fabricated within the via structure and over a top surface of the via structure. The via structure comprises a via fabricated in a hard mask layer. The RRAM device may further include a first spacer encapsulating the top electrode and the hard mask layer. In some embodiments, the RRAM device may further include a second spacer encapsulating the first spacer, the bottom electrode, and the switching oxide device.

### TECHNICAL FIELD

The implementations of the disclosure generally relate to resistive random-access memory (RRAM) devices and, more specifically, to Complementary Metal-Oxide-Semiconductor (CMOS)compatible RRAM devices and methods for fabricating the same.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a semiconductor device including a CMOS-compatible RRAM is provided. The RRAM device includes a bottom electrode; a switching oxide device including at least one transition metal oxide, a via structure fabricated on the switching oxide device, and a top electrode fabricated within the via structure and over a top surface of via structure. The via structure includes a via fabricated in a hard mask layer.

In some embodiments, the RRAM device further includes a first spacer encapsulating the top electrode and the hard mask layer.

In some embodiments, the RRAM device further includes a second spacer encapsulating the first spacer, the bottom electrode, and the switching oxide device.

In some embodiments, the second spacer further encapsulates the switching oxide device.

In some embodiments, the switching oxide device includes a layer of the transition metal oxide and a first interface layer. The first interface layer includes a first interface material that is more chemically stable than the at least one transition metal oxide.

In some embodiments, the switching oxide device further includes a second interface layer.

In some embodiments, the first interface layer is positioned between the layer of the transition metal oxide and the bottom electrode.

In some embodiments, the first interface layer is positioned between the layer of the transition metal oxide and the top electrode.

In some embodiments, the first interface material includes at least one of Al₂O₃, MgO, Y₂O₃, or La₂O₃.

In some embodiments, the RRAM device further includes a first interconnect and a second interconnect fabricated on the top electrode. The RRAM device is fabricated on the first interconnect.

In some embodiments, the RRAM device further includes a conductive via fabricated on the first interconnect, wherein the bottom electrode is fabricated on the conductive via.

In some embodiments, the top electrode includes a layer of titanium.

According to one or more aspects of the present disclosure, a method for fabricating an RRAM device is provided. The method includes fabricating a switching oxide device on a bottom electrode layer, fabricating a device stack on the switching oxide device, etching the device stack, and fabricating a first spacer along the sidewalls of the etched device stack. The device stack includes a via structure fabricated on the switching oxide device and a top electrode layer fabricated within and over the via structure.

In some embodiments, the method further includes fabricating an etch mask on the top electrode layer prior to the etching of the device stack; etching the device stack; etching, using the etching mask, the switching oxide device to fabricate a switching layer of the RRAM device; and etching, using the etching mask, the bottom electrode layer to fabricate a bottom electrode of the RRAM device. Etching the device stack includes etching, using the etching mask, the top electrode layer and a hard mask layer using the etching mask, wherein the via structure includes a via fabricated in the hard mask layer.

In some embodiments, the method further includes fabricating a second spacer along sidewalls of the first spacer and the RRAM device.

In some embodiments, the method further includes fabricating a conductive via on a first interconnect in a first lithography process using a first patterning mask, wherein the bottom electrode layer is fabricated on the conductive via.

In some embodiments, the via structure is fabricated in a second lithography process using the first patterning mask.

In some embodiments, the via structure is fabricated in a second lithography process using a second patterning mask.

In some embodiments, the second patterning mask is smaller than the first patterning mask.

In some embodiments, the method further includes fabricating a second interconnect on the top electrode of the RRAM device.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIG. 2 is a schematic diagram illustrating an example 1200 of a cross-point device in accordance with some embodiments of the present disclosure.

FIGS. 3A and 3B are schematic diagrams illustrating cross-sectional views of example semiconductor devices including a CMOS-compatible RRAM in accordance with some embodiments of the present disclosure.

FIGS. 4A-4U are schematic diagrams illustrating cross-sectional views of structures relating to fabricating RRAM devices in accordance with some embodiments of the present disclosure.

FIGS. 5A, 5B, and 5C are schematic diagrams illustrating cross-sectional views of example switching oxide device in accordance with some embodiment of the present disclosure.

FIG. 6 is a flowchart illustrating an example method for fabricating an RRAM device in accordance with some embodiments of the present disclosure.

FIG. 7 is a flowchart illustrating an example process for fabricating a switching oxide device in accordance with some embodiments of the present disclosure.

### DETAILED DESCRIPTION

Aspects of the disclosure provide CMOS-compatible resistive random-access memory (RRAM) devices and methods for fabricating the RRAM devices. An RRAM device is a two-terminal passive device with tunable resistance. The RRAM device may include a bottom electrode, a top electrode, and a switching oxide layer positioned between the bottom electrode and the top electrode. The bottom electrode may include a non-reactive metal, such as platinum (Pt), palladium (Pd), etc. The top electrode may include a reactive metal, such as tantalum (Ta), titanium (Ti), etc. The electrode including the non-reactive metal is also referred to herein as the “non-reactive electrode.” The electrode including the reactive metal is also referred to herein as the “reactive electrode.” The switching oxide layer may include a transition metal oxide, such as hafnium oxide (HfOₓ) or tantalum oxide (TaOₓ). The RRAM device may be in an initial state or virgin state and may have an initial high resistance before it is subject to a suitable electrical stimulation (e.g., a voltage or current signal applied to the RRAM device). The RRAM device may be tuned to a lower resistance state from the virgin state via a forming process or from a high-resistance state (HRS) to a lower resistance state (LRS) via a setting process. The forming process may refer to programming a device starting from the virgin state. The setting process may refer to programming a device starting from the high resistance state (HRS). After the reactive metal electrode is deposited on the switching oxide, the reactive metal can absorb oxygen from the switching oxide layer and create oxygen vacancies in the switching oxide layer, and oxygen ions can migrate in the switching oxide through a vacancy mechanism. During a forming process, a suitable programming signal (e.g., a voltage or current signal) may be applied to the RRAM device, which may cause oxygen ions to migrate from the switching oxide to the reactive electrode. As a result, a conductive channel or filament may form through the switching oxide layer (e.g., from the reactive electrode to the non-reactive electrode). The RRAM device may then be reset to a high-resistance state by applying a reset signal (e.g., a voltage signal, a current signal, etc.) to the RRAM device. The application of the reset signal to the RRAM device may cause oxygen to migrate back to the switching oxide layer and may thus interrupt the conductive filament. The RRAM device may be electrically switched between a high-resistance state and a low-resistance state by applying suitable programming signals (e.g., voltage signals, current signals, etc.) to the RRAM device. In a crossbar array circuit, the programming signals may be provided to the designated RRAM device via a selector, such as a transistor. It might be desirable to integrate RRAM arrays into CMOS circuits to implement high-density memory and/or in-memory computing applications.

To implement a one-transistor-on-resistor (1T1R) configuration, a transistor (e.g., a complementary metal-oxide-semiconductor (CMOS)) and integrated circuits may be fabricated in a front-end-of-line (FEOL) process, and an RRAM device may be subsequently fabricated in a back-end-of-line (BEOL) process. The FEOL process may include fabricating transistors and multilayer metal interconnects. The BEOL process may include fabricating RRAM devices as arrays. It might be desirable to fabricate the RRAM devices on an inner interconnect to enable the RRAM devices to be integrated as part of the CMOS process and require the RRAM devices to be CMOS-compatible. For example, it might be desirable to fabricate RRAM devices between the first metal layer (M1) and the second metal layer (M2), where M1 represents the first level of metallization closest to the substrate, while M2 is the second level.

A conventional RRAM device is typically fabricated utilizing a pillar structure by fabricating a device stack of a bottom electrode layer, a switching oxide layer, and a top electrode layer and etching the entire device stack using a single mask. However, this approach introduces the potential risk of redeposition of the bottom electrode material and/or the top electrode materials on the sidewalls of the switching oxide, which could result in shorting hazards, especially when noble metals are used as electrodes.

The present disclosure provides mechanisms for fabricating CMOS-compatible RRAM devices on an inner interconnect layer. The RRAM devices may be fabricated utilizing CMOS-compatible processes and may be resistant to annealing stresses released during the subsequent fabrication of interconnects on the RRAM devices. In some embodiments, an RRAM device may include a bottom electrode, a switching oxide device, a via structure fabricated on the switching oxide device, and a top electrode fabricated within and over the via structure. The via structure may include a hard mask layer with a via fabricated in it. The size of the RRAM device is controlled by the dimensions of the via structure, which defines the area of the switching oxide that participates in the switching process, and is not controlled by the size of the bottom electrode and/or the size of the top electrode.

In some embodiments, a first spacer may be fabricated along the sidewalls of the top electrode and the hard mask layer, encapsulating the top electrode and the hard mask layer. The first spacer may prevent etched bottom electrode materials from being backscattered on the sidewalls of the top electrode and hard mask layer. In some embodiments, a second spacer may be fabricated surrounding the first spacer to protect the entire RRAM device and encapsulate the bottom electrode.

In some embodiments, an RRAM device in accordance with the present disclosure may be fabricated on one or more first interconnect layers. One or more second interconnect layers may be fabricated on the RRAM device without deteriorating the performance of the RRAM device. The RRAM device may include a bottom electrode, a switching oxide layer, a top electrode, and one or more interface layers. The switching oxide layer may include a transition metal oxide, such as TaOₓ, HfOₓ, TiOₓ, NbOₓ, ZrOₓ, etc. Each of the interface layers may include a layer of a material that is more chemically stable than the transition metal oxide, such as Al₂O₃. In one implementation, an interface layer may be fabricated between the top electrode and the switching oxide layer. In another implementation, the RRAM device may further include an interface layer fabricated between the bottom electrode and the switching oxide layer. The interface layer(s) may enable the RRAM device to withstand the stresses released from the subsequent fabrication processes of the interconnect layers (e.g., metallization and annealing processes for fabricating the interconnect layers on the RRAM device). Thus, the RRAM device is CMOS-compatible as it may be fabricated in a CMOS process. The RRAM device is annealing resistant and may be fabricated on an inner interconnect layer.

Accordingly, the present disclosure provides mechanisms for fabricating RRAM devices using CMOS-compatible processes. By fabricating the RRAM devices on the inner interconnects having relatively smaller sizes and spacings, the mechanisms described herein may enhance the scalability of a crossbar array of RRAM devices and may enable high-density memory and/or computing applications.

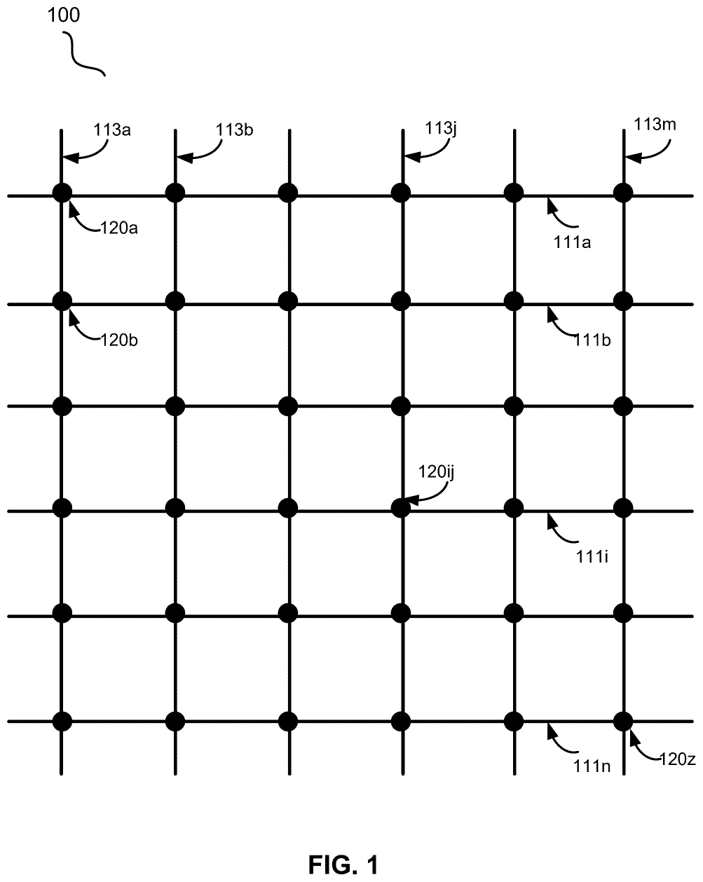

FIG. 1 is a schematic diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . 111i, . . . 111n, and column wires 113a, 113b, . . . 113j,. 113m for an n-row by m-column crossbar array. The crossbar circuit 100 may further include cross-point devices 120a, 120b, . . . 120z, etc. Each of the cross-point devices may connect a row wire and a column wire.

For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111 may include a first row wire 111a, a second row wire 111b, . . . 111i, . . . and an n-th row wire 111n. Each of row wires 111a, . . . 111n may be and/or include any suitable electrically conductive material. In some embodiments, each row wire 111a-n may be a metal wire.

Column wires 113 may include a first column wire 113a, a second column wire 113b, . . . and an m-th column wire 113m. Each of column wires 113a-m may be and/or include any suitable electrically conductive material. In some embodiments, each column wire 113a-m may be a metal wire.

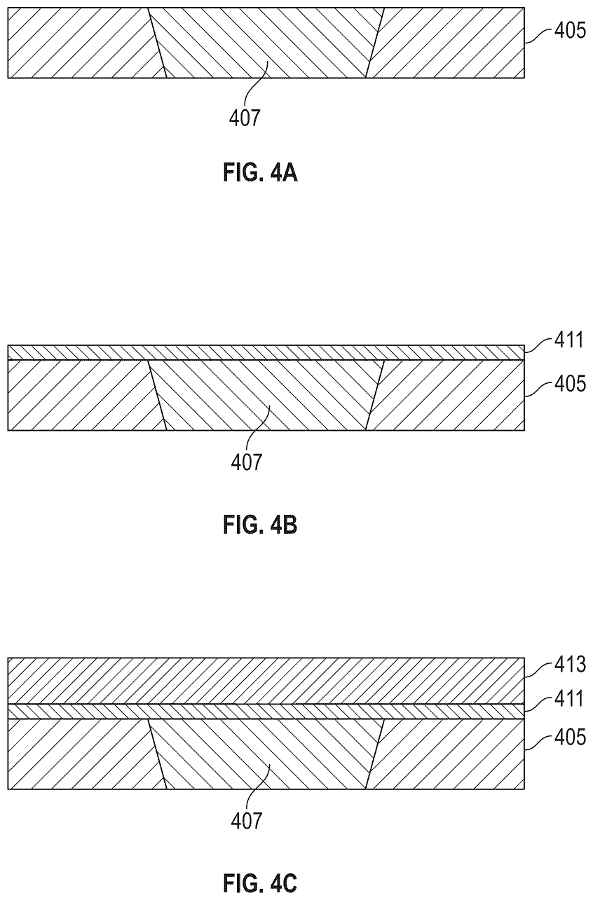

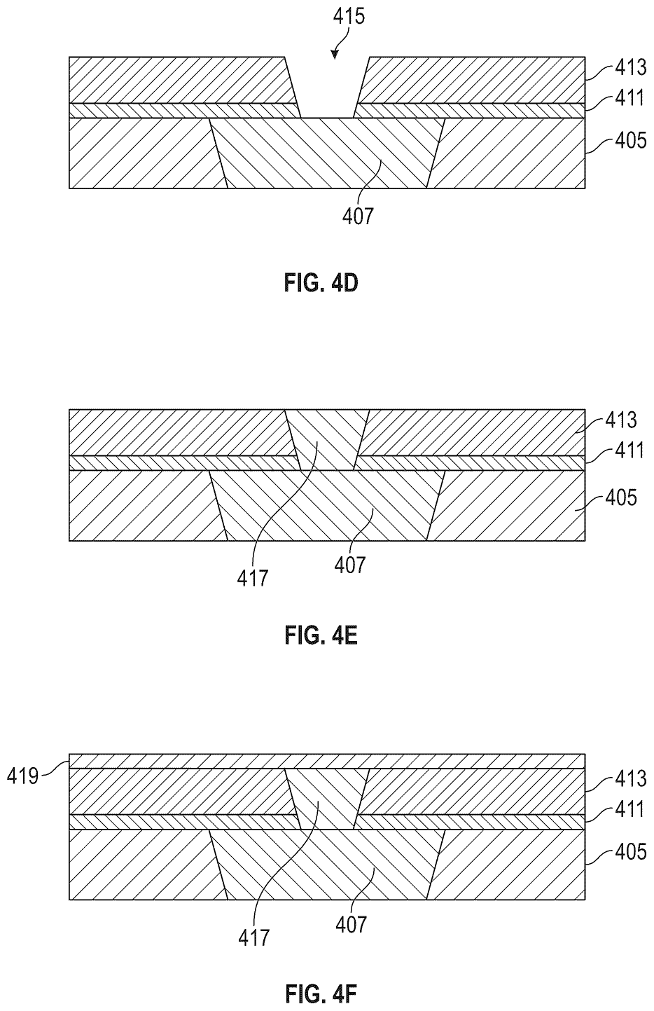

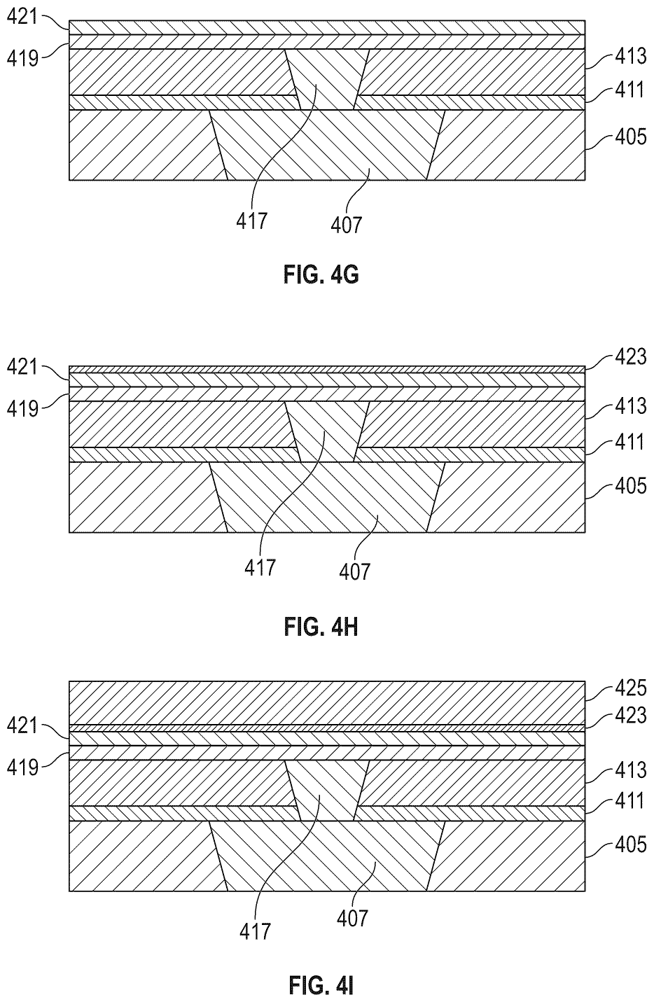

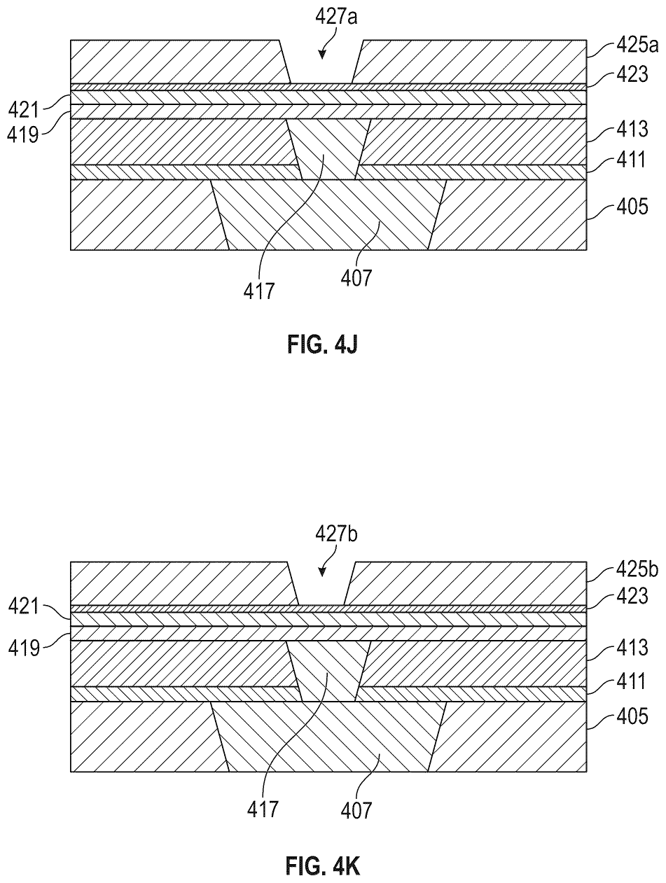

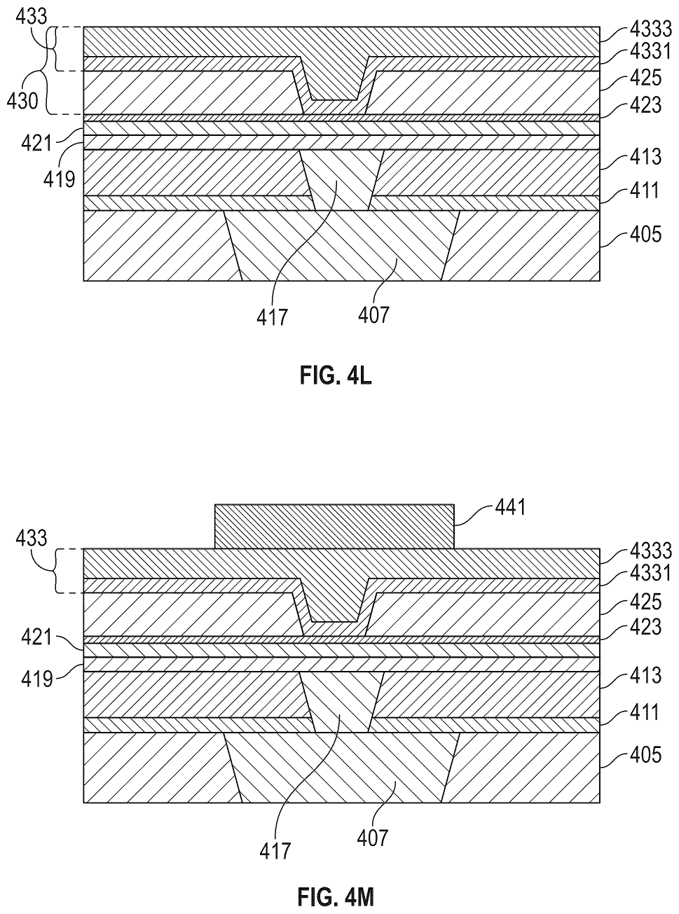

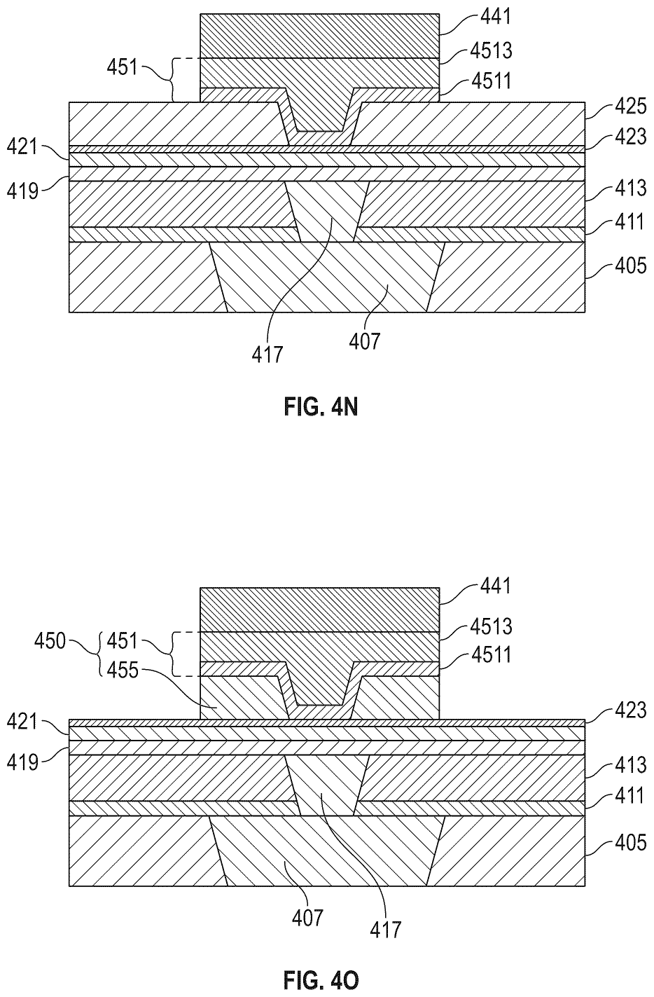

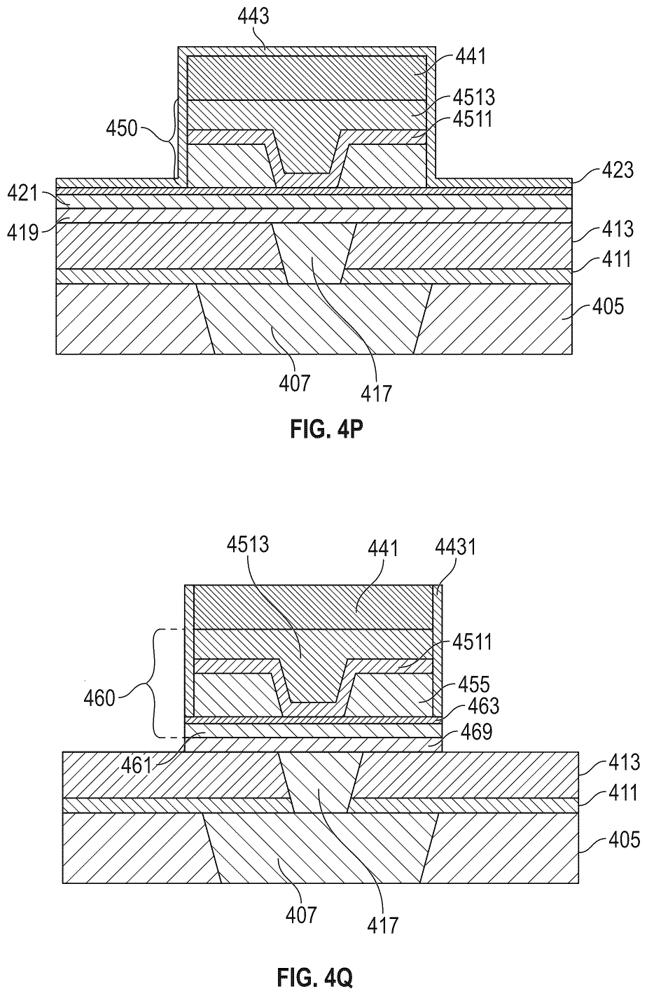

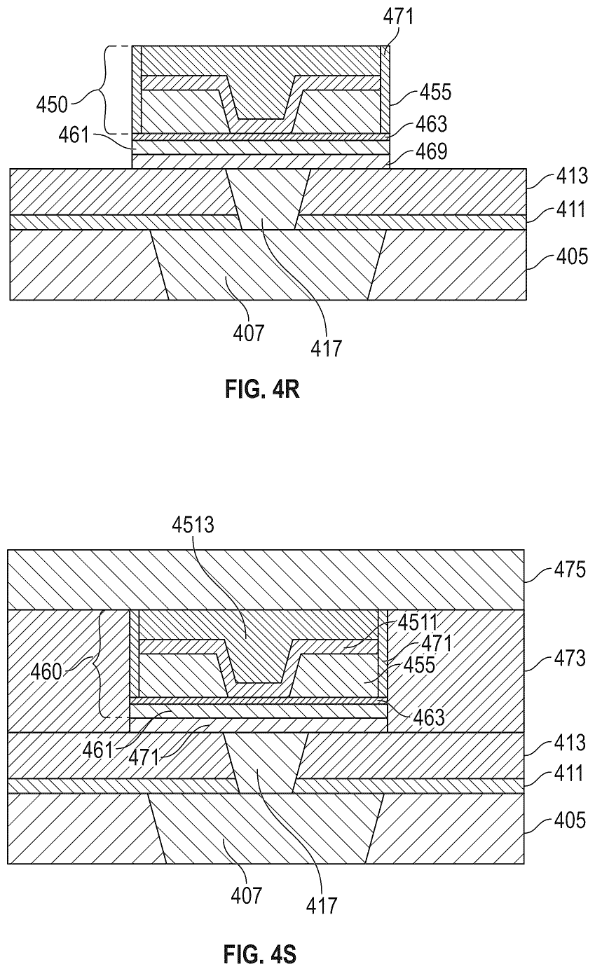

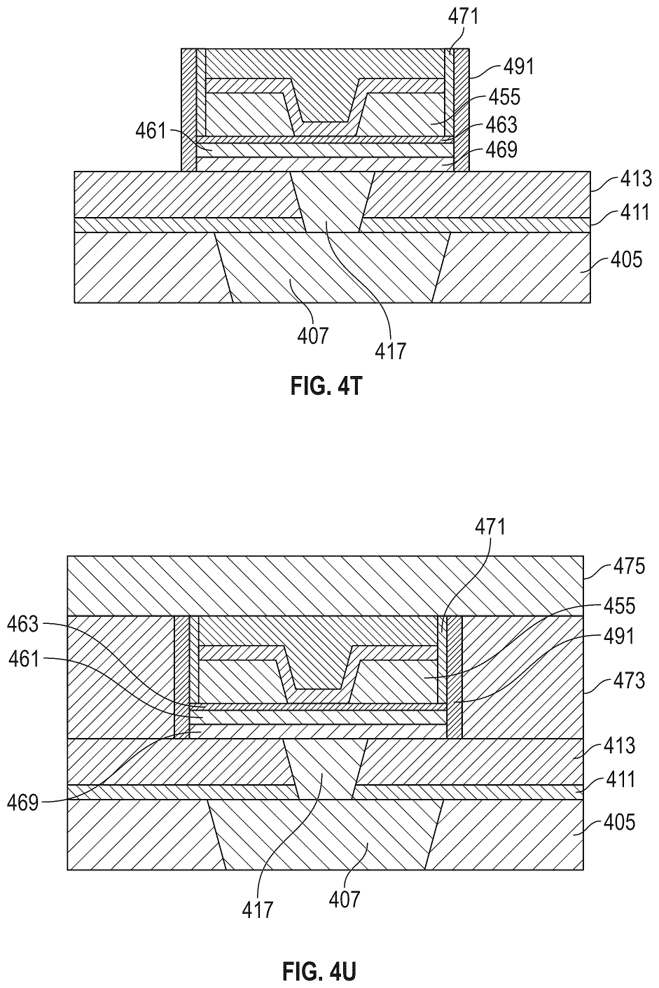

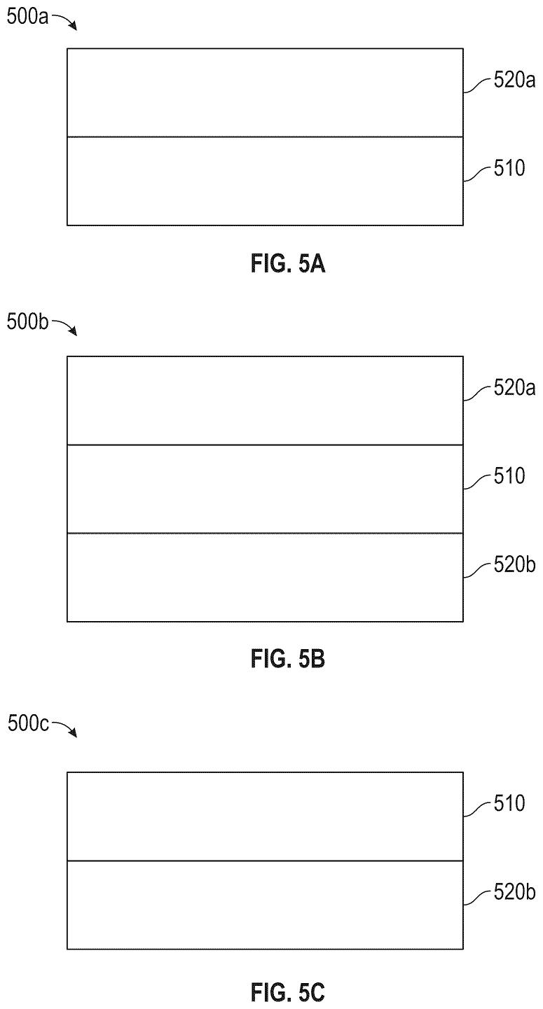

Each cross-point device 120 may be and/or include any suitable device with tunable resistance, such as a memristor, phase-change memory (PCM) devices, floating gates, spintronic devices, resistive random-access memory (RRAM), static random-access memory (SRAM), etc. In some embodiments, one or more of cross-point devices 120 may include an RRAM device and a transistor as described in connection with FIGS. 4A-5C.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. According to Kirchhoff's law, the total current generated by all the devices on each column forms the output signal, which may be read from the columns (e.g., via ADC outputs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is outputted via each column wire and may be accumulated according to Kirchhoff's current law. This may enable in-memory computing (IMC) through parallel multiplications and summations performed in the crossbar arrays.

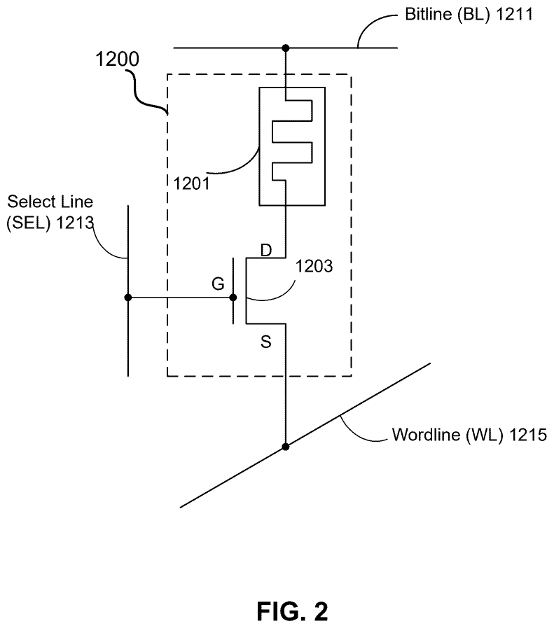

FIG. 2 is a schematic diagram illustrating an example 1200 of a cross-point device in accordance with some embodiments of the present disclosure. As shown, cross-point device 1200 may connect a bitline (BL) 1211, a select line (SEL) 1213, and a wordline (WL) 1215. The bitline 1211 and the wordline 1215 may be a column wire and a row wire as described in connection with FIG. 1, respectively.

Cross-point device 1200 may include an RRAM device 1201 and a transistor 1203. A transistor is a three-terminal device, which may be marked as gate (G), source(S), and drain (D), respectively. The transistor 1203 may be serially connected to RRAM device 1201. As shown in FIG. 2, the bottom electrode of the RRAM device 1201 may be connected to the drain of transistor 1203. The top electrode of the RRAM device 1201 may be connected to the bitline 1211. The source of the transistor 1203 may be connected to the wordline 1215. The gate of the transistor 1203 may be connected to the select line 1213. RRAM device 1201 may include one or more RRAM devices as described in connection with FIGS. 4A-5C below. Cross-point device 1200 may also be referred to as in a 1-transitor-1-resistor (1T1R) configuration. The transistor 1203 may perform as a selector as well as a current controller, which may set the current compliance, to the RRAM device 1201 during programming. The gate voltage on transistor 1203 can set current compliances to cross-point device 1200 during programming and can thus control the conductance and analog behavior of cross-point device 1200. For example, when cross-point device 1200 is set from a high-resistance state to a low-resistance state, a set signal (e.g., a voltage signal, a current signal) may be provided via the bitline (BL) 1211. Another voltage, also referred as a select voltage or gate voltage, may be applied via the select line (SEL) 1213 to the transistor gate to open the gate and set the current compliance, while the wordline (WL) 1215 may be set to ground. When cross-point device 1200 is reset from the low-resistance state to the high-resistance state, a gate voltage may be applied to the gate of the transistor 1203 via the select line 1213 to open the transistor gate. Meanwhile, a reset signal may be sent to the RRAM device 1201 via the wordline 1215, while the bitline 1211 may be set to ground.

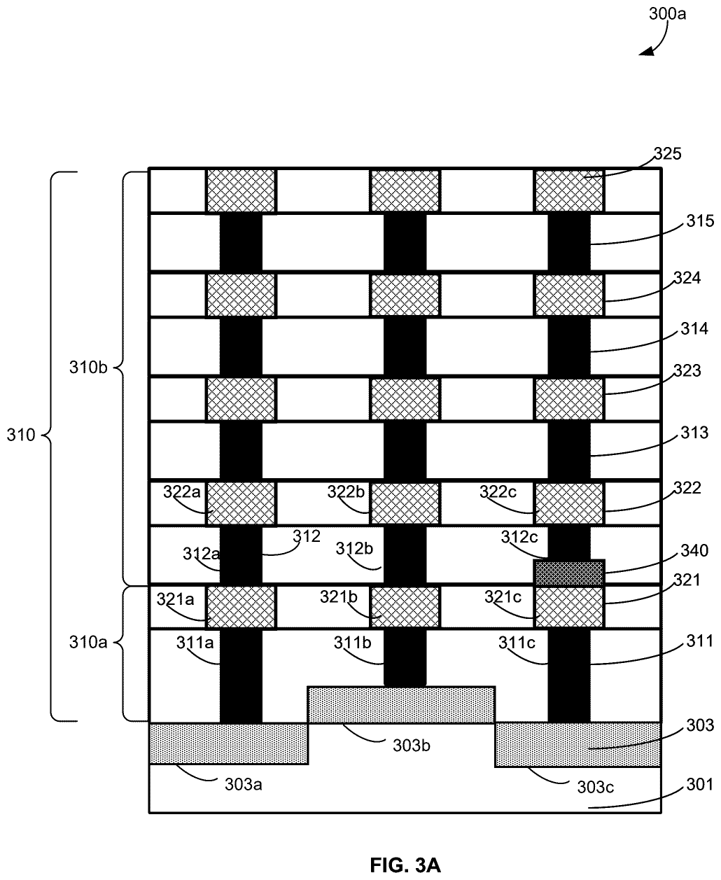

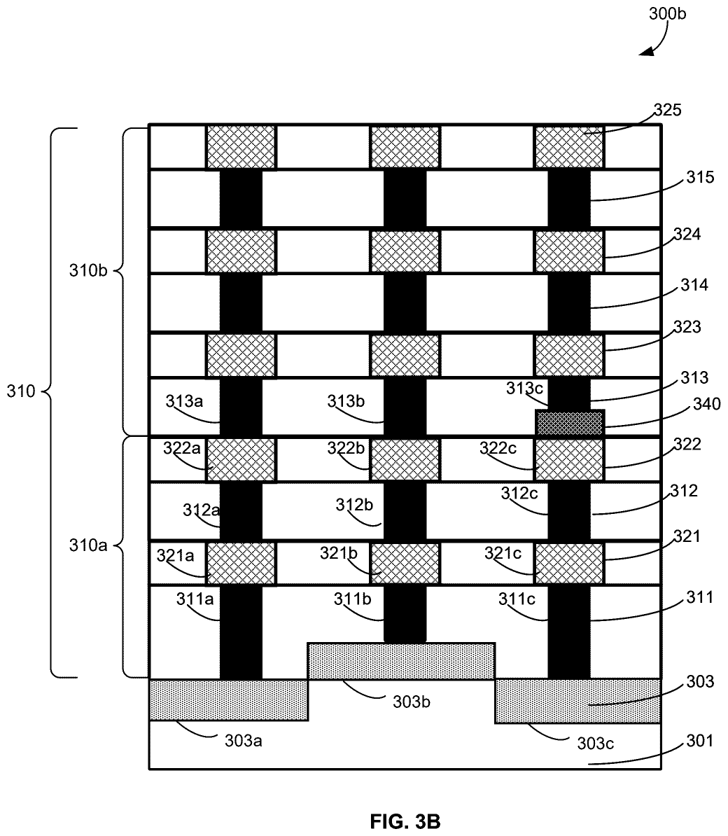

FIGS. 3A and 3B are schematic diagrams illustrating cross-sectional views of example semiconductor devices 300a and 300b including a CMOS-compatible RRAM in accordance with some embodiments of the present disclosure.

As shown, a transistor 303 is fabricated on a substrate 301. The transistor 303 may include a source region 303a, a gate 303b, and a drain region 303c. While one transistor is shown in FIG. 3A, this is merely illustrative. Multiple transistors (not shown) may be fabricated on the substrate 301 in some embodiments. The transistors may be isolated by suitable insulator and/or dielectric material.

The semiconductor device 300a may include interconnect layers 310 fabricated on the transistor 303 and the substrate 301. Each of the interconnect layers 310 may provide electrical connectivity between the transistor 303 and/or one or more other devices (e.g., one or more other transistors, one or more other RRAM devices, etc.). The interconnect layers 310 may include, for example, via layers (or via layers) 311, 312, 313, 314, 315, and 316 and metal layers (or pad layers) 321, 323, 324, 325, and 326. Each of the via layers may include one or more metallic vias. Each of the metallic vias may include a suitable metallic material, such as Al, Cu, W, etc. Each of the metal layers may include one or more metallic pads. Each of the metallic pads may include a suitable metallic material, such as Al, Cu, W, etc. For example, the via layer 311 may include metallic vias 311a, 311b, and 311c that may be connected to the source region 303a, the gate 303b, and the drain region 303c of the transistor 303, respectively. In some embodiments, the via layer 311 may include tungsten (W) vias and doped polycrystalline Si (poly-Si) terminals where poly-Si terminals may be in direct contact to the gate 303b, the source region 303a, and the drain region 303c of the transistor 303. The tungsten vias may be in direct contact with the poly-Si terminals. The other via layers and metal layers above the via layer 311 may be fabricated with Cu, W, Al, etc. The metal layer 321 may include metallic pads 321a, 321b, and 321c. The metallic pads 321a, 321b, and 321c may be connected to the metallic vias 311a, 311b, and 311c, respectively.

As shown, a pair of neighboring metal layers may be connected via a via layer fabricated between the neighboring metal layers. For example, a first metal layer 321 may be connected to a second metal layer 322 through a via layer 312. In particular, the metallic pad 322a of the metal layer 322 may be connected to the metallic pad 321a of the metal layer 321 through the metallic via 312a. The metallic pad 322b of the metal layer 322 may be connected to the metallic pad 321b of the metal layer 321 through the metallic via 312b. The metallic pad 322c of the metal layer 322 may be connected to the metallic pad 321c of the metal layer 321 through the metallic via 312c and the RRAM device 340.

The interconnect layers 310 may have varying dimensions. The sizes of the metallic pads of the metal layers 321, 322, 323, 324, 325, . . . 326 may increase sequentially. Similarly, the sizes of the metallic via in the via layers 311, 312, 313, 314, 315, . . . 316 may increase sequentially. For example, the semiconductor device 300 may be part of a 65 nm technology node. The width and the spacing of the metallic pads of the metal layer 321 may be about 90 nm. The width and the spacing of the metallic pads of the metal layers 322 and 323 may be about 100 nm. The width and the spacing of the metallic pads of the metal layers 326 may be about 400 nm.

An RRAM device 340 may be fabricated during the fabrication of the interconnect layers 310. As such, the RRAM device 340 is referred to as a CMOS-compatible RRAM device. For example, one or more first interconnect layers 310a may be fabricated on the transistor 303 and/or the substrate 301. The RRAM device 340 may be fabricated on a metallic pad or a metallic via of the top interconnect layer of the first interconnect layers 310a. One or more second interconnect layers 310b may then be fabricated on the RRAM device 340 and the first interconnect layers 310a. More particularly, for example, a metallic pad or metallic via of the bottom interconnect layer of the second interconnect layers 310b may be fabricated on the RRAM device 340 and may directly contact the RRAM device 340. In some embodiments, as shown in FIG. 3A, the first interconnect layers 310a may include the via layer 311 and the metal layer 321. The metal layer 321 may be regarded as being the top interconnect layer of the first interconnect layers 310a. The RRAM device 340 may be fabricated on the metallic pad 321c of the metal layer 321. The RRAM device 340 is connected to the drain region 303c of the transistor 303 through the metallic pad 321c of the metal layer 321 and the metallic via 311c of the via layer 311. The metallic via 312c of the via layer 312 may be fabricated on the RRAM device 340 and may be connected to a bitline of a circuit including the RRAM device 340 (e.g., the bitline 1211 of FIG. 2). The metallic vias 312a and 312b of the via layer 312 may be fabricated on the metallic pads 321a and 321b, respectively. The metal layer 312 may be regarded as being the bottom interconnect layer of the second interconnect layers 310b. The second interconnect layers 310b may include one or more metal layers and/or via layers fabricated on the metal layer 321 (e.g., metal layers 322, 323, 324, and 325 and via layers 312, 313, 314, and 315).

In some embodiments, as shown in FIG. 3B, the RRAM device 340 may be fabricated on the metallic pad 322c of the metal layer 322. The via layer 313 may be fabricated on the RRAM device 340. In particular, the metallic via 313c of the via layer 313 is fabricated on the RRAM device 340 and directly contacts the RRAM device 340. In such embodiments, the first interconnect layers may include the via layer 311, the metal layer 321, the via layer 312, and the metal layer 322. The metal layer 322 may be regarded as being the top interconnect layer of the first interconnect layers 310a. The second interconnect layers 310b may include the via layers 313, 314, and 315 and the metal layers 323, 324, and 325. The via layer 313 may be regarded as the bottom interconnect layer of the second interconnect layers 310b.

As will be described in greater detail below, the RRAM device 340 may be resistant to the annealing processes involved in the fabrication of interconnect layers. As a result, the annealing steps required during interconnect fabrication may not deteriorate the performance of the RRAM device.

Although the total processing steps involved in fabricating the interconnect layers 310 in FIGS. 3A and 3B may be the same, fabricating the first interconnect layers 310a in FIG. 3B includes more steps than fabricating the first interconnect layers 310a in FIG. 3A, while fabricating the second interconnect layers 301b in FIG. 3B includes fewer steps than fabricating the second interconnect layers 310b in FIG. 3A. The RRAM device 340 is connected to the drain region 303c of the transistor 303 through the metallic pad 322c of the metal layer 322, the metallic via 312c of the via layer 312, the metallic pad 321c of the metal layer 321, and the metallic via 311c of the via layer 311. Metallic via 313c of the via layer 313 may be fabricated on the RRAM device 340 and may be connected to the bitline of the circuit (e.g., the bitline 1211 of FIG. 2). Metallic vias 313a and 313b of the via layer 313 may be fabricated on the metallic pads 322a and 322b, respectively.

While certain interconnect layers (e.g., metal layers and via layers) are shown in FIGS. 3A-3B, this is merely illustrative. The semiconductor device 300a and/or 300b may include any suitable number of interconnect layers for implementing various integrated circuits. The first interconnect layers 310a and the second interconnect layers 310b may include any suitable number of interconnect layers. For example, the RRAM device 340 may be fabricated on the metal layer 323 in some embodiments.

FIGS. 4A-4U are schematic diagrams illustrating cross-sectional views of structures relating to fabricating RRAM devices and semiconductor devices incorporating RRAM devices in accordance with some embodiments of the present disclosure.

As shown in FIG. 4A, a substrate 405 may be provided. Substrate 405 may include a transistor (not shown) and a first interconnect 407. First interconnect 407 may include a metallic pad and/or metallic via as described in connection with FIGS. 3A and 3B. In some embodiments, first interconnect 407 may be part of an inner interconnect layer 310A as described in connection with FIGS. 3A-3B.

As shown in FIG. 4B, a first dielectric layer 411 may be fabricated on substrate 405. First dielectric layer 411 may include a layer of a first dielectric material, such as silicon nitride (SiN).

As shown in FIG. 4C, a second dielectric layer 413 may be fabricated on first dielectric layer 411. Second dielectric layer 413 may include one or more second dielectric materials with a low dielectric constant (low-k). Low-k dielectric materials may be dielectric materials with a dielectric constant lower than that of silicon dioxide (SiO₂), which has a value of 3.9. In some embodiments, a low-k dielectric material may have a dielectric constant between 2.5 and 3.5. The second dielectric material may have a lower dielectric constant than the first dielectric material. In some embodiments, the second dielectric material may be a low dielectric constant oxide (also referred to as the “first low dielectric constant oxide”), such as porous silicon dioxide (SiO₂), fluorinated silicon dioxide (SiOF), carbon-doped SiO2, etc.

As shown in FIG. 4D, a first via 415 may be fabricated by patterning and etching first dielectric layer 411 and second dielectric layer 413. The fabrication of first via 415 (e.g., the etching of first dielectric layer 411 and second dielectric layer 413) may expose at least a portion of the top surface of first interconnect 407.

As shown in FIG. 4E, a conductive via 417 may be fabricated by depositing suitable conductive materials in first via 415. Conductive via 417 may include, for example, metals (e.g., Cu, Al, W, etc.), alloys, metal nitrides, etc.

In some embodiments, a barrier layer 419 may be fabricated on second dielectric layer 413 and conductive via 417, as shown in FIG. 4F. Barrier layer 419 may prevent the metallic material in the first interconnect (e.g., Cu) from diffusing into the RRAM device to be fabricated on the conductive via 417 and damaging the device. Barrier layer 419 may include a layer of tantalum nitride (TaN) in some embodiments.

As shown in FIG. 4G, a bottom electrode layer 421 may be fabricated on top of the barrier layer 419. The bottom electrode layer may include a tantalum (Ta) adhesion layer and a noble metal such as platinum (Pt) or a nitride layer. For example, the bottom electrode layer may include a Ta/Pt stack or other materials such as iridium (Ir), palladium (Pd), titanium nitride (TiN), tantalum nitride (TaN), etc.

As shown in FIG. 4H, a switching oxide device 423 may be fabricated on bottom electrode layer 421. Switching oxide device 423 may include a switching oxide layer and one or more interface layers. In some embodiments, switching oxide device 423 may include one or more memristor stacks as described in connection with FIGS. 5A, 5B, and 5C.

As shown in FIG. 4I, a hard mask layer 425 may be fabricated on switching oxide device 423. Hard mask layer 425 may include silicon nitride (Si₃N₄), silicon dioxide (SiO₂), silicon carbide (SiC), silicon oxynitride (SiOₓN_{y}), and/or any other suitable material that may function as a hard mask.

As shown in FIG. 4J, a second via 427a may be fabricated in hard mask layer 425. The fabrication of second via 427a may expose a portion of the top surface of bottom electrode layer 421. The etched hard mask layer 425 with second via 427a may be referred to as a via structure 425a. In one implementation, first via 415 and second via 427a may be fabricated in lithography processes using the same patterning mask. In such implementation, the size of the RRAM device to be fabricated on second via 427a is the same as the size of the conductive via 417. In another implementation, as shown in FIG. 4K, a second via 427b may be fabricated using a smaller patterning mask to further scale down the size of the RRAM device to be fabricated. First via 415 and second via 427b may be fabricated in lithography processes using different patterning masks. The etched hard mask layer 425 with second via 427b may be referred to as via structure 425b.

As shown in FIG. 4L, a top electrode layer 433 may be fabricated in second via 427 and on hard mask layer 425. In particular, top electrode layer 433 may be conformally deposited in second via 427a or 427b and on hard mask layer 425. Second via 427a or 427b may be completely filled by a portion of top electrode layer 433. Top electrode layer 433 may further extend over the filled second via 427 and the top surface of hard mask layer 425. In some embodiments, top electrode layer 433 may include a layer of tantalum 4331 fabricated in via 427 and on hard mask layer 425. Top electrode layer 433 may further include a metal nitride layer 4333. The metal nitride layer 4333 may include, for example, one or more layers of tantalum nitride (TaN), titanium nitride (TiN), etc. The top electrode layer 433 and hard mask layer 425 as shown in FIG. 4L may be collectively referred to as a device stack 430.

As shown in FIG. 4M, an etch mask 441 may be fabricated on top electrode layer 433. Etch mask 441 may include, for example, silicon nitride, silicon dioxide, or any other suitable material that may protect specific regions of the top electrode layer during subsequent etching processes, allowing for selective removal of material in unprotected areas.

As shown in FIG. 4N, a top electrode 451 may be fabricated by etching top electrode layer 433. Etch mask 441 may define the dimensions of the etched top electrode layer 433, as the portion of top electrode layer 433 that is covered by etch mask 441 is not etched. The etching of layers of 4331 and 4333 may form layers 4511 and 4513, respectively.

As shown in FIG. 4O, hard mask layer 425 may be etched to form a hard mask layer 455. Etch mask 441 may also function as a patterning and etch mask during the etching of hard mask layer 425. More particularly, the portion of hard mask layer 425 that is covered by etch mask 441 is not etched. In some embodiments, switching oxide device 423 may also be etched during the etching of hard mask layer 425 and top electrode layer 433. Alternatively, switching oxide device 423 is not etched in some embodiments. Top electrode 451 and hard mask layer 455 (the etched device stack 430) may also be collectively referred to as a device stack 450.

As shown in FIG. 4P, a first spacer layer 443 may be fabricated on etch mask 441, switching oxide device 423, and side walls of device stack 450. First spacer layer 443 may include one or more dielectric and/or insulating materials, such as SiO₂, SiN, SiOxNy, alternating layers of SiO₂ and SiN, etc.

As shown in FIG. 4Q, first spacer layer 443 may be etched to selectively remove the portions of spacer layer 443 fabricated on the top surface of etch mask 441 and the top surface of switching oxide device 423. The etched spacer layer 4431 may encapsulate etch mask 441 and device stack 450. Etch mask 441 may serve as a patterning and etch mask during the etching of first spacer layer 443. Meanwhile, switching oxide device 423 may be etched to fabricate a switching oxide device 463 of RRAM device 460. Bottom electrode layer 421 may be etched to fabricate a bottom electrode 461 of RRAM device 460. Barrier layer 419 may be etched to fabricate a barrier layer 469. First spacer layer 443 may prevent etched bottom electrode materials from being backscattered on the sidewalls of top electrode 451 and hard mask layer 455.

The portion of top electrode 451 that is deposited at the bottom of the via structure may directly contact the switching oxide layer on the bottom electrode 461. The remaining portion of the top electrode 451 does not make direct contact with the switching oxide device 463 and does not participate in the switching mechanism of the RRAM device 460. Therefore, the size (or dimensions) of RRAM device 460 is determined by the size (or dimensions) of the via structure, not determined by the size of the bottom electrode and/or the top electrode.

As shown in FIG. 4R, etch mask 441 may be removed. The etch mask 441 can be removed using a selective etching process, such as wet etching or dry etching (e.g., reactive ion etching). The removal of etch mask 441 may also remove a portion of spacer layer 4431 that covers the sidewall of the device stack 450 and may fabricate a spacer 471 (also referred to as the first spacer 471).

As shown in FIG. 4S, a second interconnect 475 may be fabricated on RRAM device 460. For example, a third dielectric layer 473 may be fabricated on second dielectric layer 413 and along the sidewalls of RRAM device 460. Third dielectric layer 473 may include one or more third dielectric materials with a low dielectric constant. The third dielectric material may have a lower dielectric constant than the first dielectric material. In some embodiments, the third dielectric material may be a low dielectric constant oxide (also referred to as the “second low dielectric constant oxide”), such as porous silicon dioxide (SiO₂), fluorinated silicon dioxide (SiOF), carbon-doped SiO2, etc.

As will be described in greater detail in connection with FIGS. 5A-5C, the RRAM device 460 may be resistant to the annealing processes involved in the fabrication of subsequent interconnect layers. As a result, the annealing steps required during the fabrication of the second interconnect may not deteriorate the performance of the RRAM device 460.

In some embodiments, as shown in FIG. 4T, a second spacer 491 may be fabricated to encapsulate first spacer 471 and the entire RRAM device 460. Second spacer 491 may protect and encapsulate bottom electrode 461, the barrier layer 469, and switching oxide device 463. The second spacer may be conformally deposited and may encapsulate the first spacer, surrounding both the lateral (sidewall) portions of the first spacer and the sidewall of the bottom electrode, the barrier layer, and the switching oxide device of the RRAM device. Specifically, the second spacer is positioned adjacent to the first spacer, extending both laterally outward from the first spacer and vertically downward, covering the sidewall of the bottom electrode, the sidewall of the barrier layer and the switching oxide device of the RRAM device.

Second interconnect 475 may then be fabricated on the top surface of the top electrode and on the top surface of the third dielectric material as shown in FIG. 4U.

FIGS. 5A, 5B, and 5C are schematic diagrams illustrating cross-sectional views of example switching oxide device 500a, 500b, and 500c, in accordance with some embodiment of the present disclosure.

As shown in FIG. 5A, switching oxide device 500a may include a switching oxide layer 510 and an interface layer 520a. The interface layer 520a (also referred to as the “interface layer A” or the “first interface layer”) is fabricated between the top electrode of the RRAM device (not shown in FIG. 5A) and the switching oxide layer 510.

The switching oxide layer 510 may include one or more transition metal oxides, such as TaOₓ, HfOₓ, TiOₓ, NbOₓ, ZrOₓ, etc., in binary oxides, ternary oxides, and high order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). As an example, switching oxide layer 510 may include Ta₂O₅. As the other example, the switching oxide layer 510 may include HfO₂.

The interface layer 520a may be and/or include a film of a first interface material that is more chemically stable than the transition metal oxide(s) in switching oxide layer 510. As a result, the first interface material may not react with the transition metal oxide(s) of switching oxide layer 510. As an example, the transition metal oxide(s) of the switching oxide layer may be and/or include one or more transition metal oxides, such as at least one of HfOₓ or TaO_{y}, wherein x≤2.0, and wherein y≤2.5, and the first interface material may include Al₂O₃, MgO, Y₂O₃, La₂O₃, etc.

The interface layer 520a may prevent excessive diffusion and reaction between RRAM switching oxide and the electrodes caused by additional thermal exposure to the RRAM device during the subsequent fabrication of interconnect layers on the RRAM device 340.

The interface layer 520a may have a suitable thickness to achieve desirable forming gas anneal (FGA) resistance. For example, a relatively thicker interface layer may be more FGA resistant than a relatively thinner interface layer. In one implementation, the interface layer 520a may include a discontinuous film of Al₂O₃, SiO₂, Y₂O₃, etc. In another implementation, the interface layer 520a may include a continuous film of Al₂O₃, SiO₂, Y₂O₃, La₂O₃, etc.

In some embodiments, as illustrated in FIG. 5B, a switching oxide device 500b may include multiple interface layers. For example, an interface layer 520b (also referred to as the “interface layer B” or the “second interface layer”) may be fabricated between the bottom electrode of the RRAM device (not shown in FIG. 5B) and switching oxide layer 510. Interface layer 520b may be and/or include a film of a second interface material that is more chemically stable than the transition metal oxide(s) in switching oxide layer 510. As a result, the second interface material may not react with the transition metal oxide(s) of switching oxide layer 510. As an example, the transition metal oxide(s) of the switching oxide layer may be and/or include one or more transition metal oxides, such as at least one of HfOₓ or TaO_{y}, wherein x≤2.0, and wherein y≤2.5, and the second interface material may include Al₂O₃, MgO, Y₂O₃, La₂O₃, etc. The first interface material in interface layer 520a may or may not be the same as the second interface material in interface layer 520b.

The interface layer 520b may have a desired thickness to achieve desirable FGA resistance. For example, a relatively thicker interface layer may be more FGA resistant than a relatively thinner interface layer. In one implementation, the interface layer 520b may include a discontinuous film of Al₂O₃, SiO₂, Y₂O₃, etc. In another implementation, interface layer 520b may include a continuous film of Al₂O₃, SiO₂, Y₂O₃, etc.

Referring to FIG. 5C, switching oxide device 500c includes switching oxide layer 510 and interface layer 520b in some embodiments.

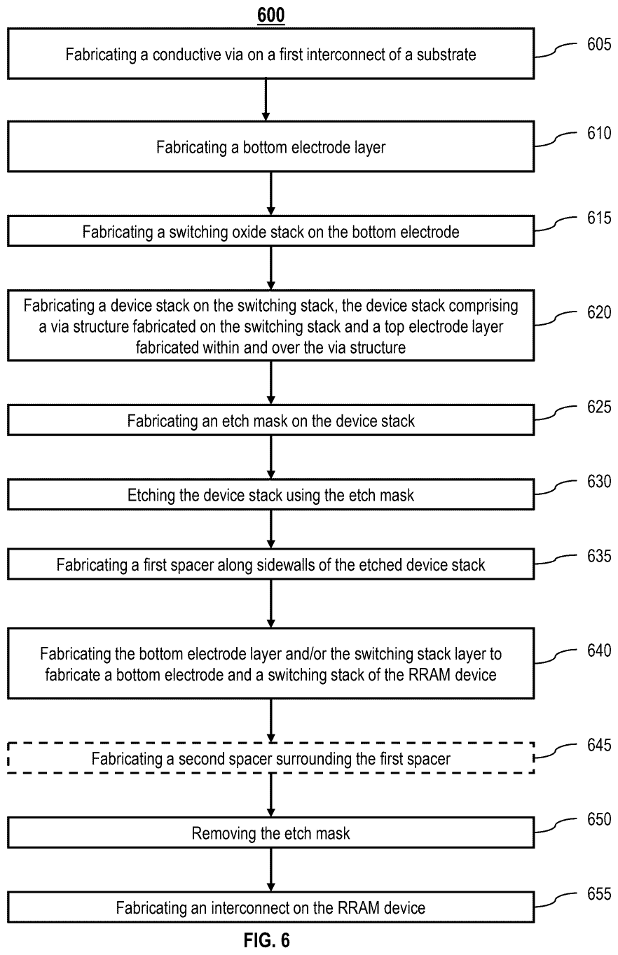

FIG. 6 is a flowchart illustrating an example process 600 for fabricating an RRAM device in accordance with some embodiments of the present disclosure.

At 605, a conductive via may be fabricated on a first interconnect of a substrate. The first interconnect may be a metallic via or a metallic pad. The substrate may be a CMOS substrate in some embodiments. Fabricating the conductive via may involve fabricating one or more dielectric layers (e.g., a first dielectric layer 411 of FIG. 4B and a second dielectric layer 413 of FIG. 4C). A first via may then be fabricated in the dielectric layers. The conductive via may be fabricated by depositing suitable conductive materials (e.g., a metal, an alloy, etc.) in the first via. In some embodiments, the first via may be fabricated using a first patterning mask in a lithography process. The patterning mask may define the dimensions of the first via and the conductive via.

At 610, a bottom electrode layer may be fabricated. In some embodiments, a TaN layer may be fabricated between the bottom electrode layer and the conductive via. In some embodiments, an adhesion layer, such as a layer of Ta, may be fabricated between the TaN layer and the bottom electrode layer. Fabricating the bottom electrode layer may involve depositing one or more layers of one or more non-active metals, such as Pt, Pd, Ir, etc., utilizing a physical vapor deposition (PVD) technique, a chemical vapor deposition (CVD) technique, a sputtering deposition technique, an atomic layer deposition (ALD) technique, and/or any other suitable deposition technique. In some embodiments, fabricating the bottom electrode layer may involve depositing one or more layers of Pt. In some embodiments, fabricating the bottom electrode layer may include depositing a metal nitride on the conductive layer. The metal nitride may include, for example, tantalum nitride, titanium nitride, etc.

At 615, a switching oxide stack may be fabricated on the bottom electrode layer.

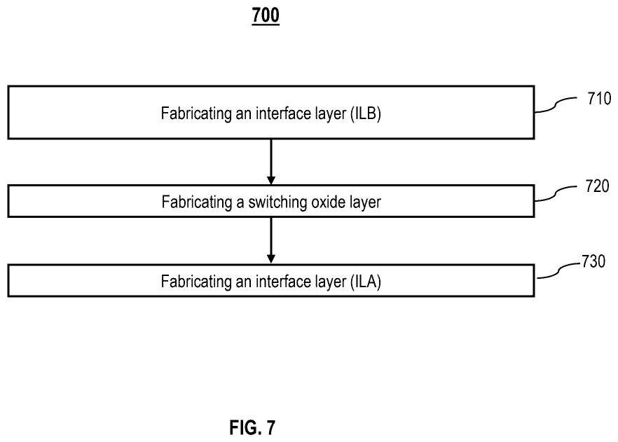

Fabricating the switching oxide device may involve fabricating a switching oxide layer containing one or more transition metal oxides. The transition metal oxides may include, for example, TaOₓ, HfOₓ, TiOₓ, NbOₓ, ZrOₓ, etc. Fabricating the switching oxide device may further involve fabricating one or more interface layers as described in connection with FIGS. 5A-5C. In some embodiments, the switching oxide device may be fabricated by performing operations described in connection with FIG. 7.

At step 620, a device stack may be fabricated on the conductive via. The device stack may include a via structure fabricated on the switching oxide device and a top electrode layer fabricated within and over the via structure. The via structure may include a hard mask layer (e.g., a layer of SiO₂, Si₃N₄, etc.) with a via fabricated in it. The top electrode layer may be fabricated by depositing one or more suitable electrode materials in the via fabricated until the via is filled with the electrode materials. The deposition of the electrode materials may continue to form a conformal layer over the hard mask layer and the via structure. Fabricating the top electrode layer may involve depositing one or more suitable metallic materials that are electrically conductive and reactive to the switching oxide in the switching oxide layer, such as Ta, Hf, Ti, TiN, TaN, etc. The top electrode may include one or more alloys. The top electrode layer may be fabricated utilizing PVD, CVD, ALD, and/or any other suitable deposition technique. The device stack may be the device stack 430 as described in connection with FIG. 4L above.

At step 625, an etch mask may be fabricated on the device stack. For example, the etch mask may be fabricated by depositing a layer of etch mask material and patterned by using photolithography to define the specific areas where etching will occur.

At step 630, one or more portions of the device stack are etched using the etch mask. For example, the top electrode layer may be etched to fabricate a top electrode of the RRAM device. The hard mask layer comprises the via device structure may be etched as well using the same etch mask.

At step 635, a first spacer may be fabricated along sidewalls of the etched device stack. For example, a first spacer layer may be conformally deposited along the sidewalls of the etch mask, the side wall of the top electrode, and the side wall of the hard mask layer, and on the top surface of the switching stack. The first spacer layer may then be etched to fabricate the first spacer.

Fabricating the first spacer layer may involve depositing SiO₂, SiN, SiOₓN_{y}, alternating SiO2/SiN layers using techniques such as atomic layer deposition (ALD), chemical vapor deposition (CVD), plasma-enhanced CVD (PECVD), etc.

At step 640, the bottom electrode layer and/or the switching oxide device may be etched using the etch mask to fabricate a bottom electrode and a switching oxide device of the RRAM device. The adhesion layer Ta under bottom electrode and the barrier layer TaN may also be etched in step 640.

In some embodiments, a second spacer may be fabricated outside the first spacer at step 645. The second spacer may be conformally deposited and may encapsulate the first spacer, surrounding both the lateral (sidewall) portions of the first spacer and the sidewall of the bottom electrode and the switching oxide device of the RRAM device. Specifically, the second spacer is positioned adjacent to the first spacer, extending both laterally outward from the first spacer and vertically downward, covering the sidewall of the bottom electrode, the side wall of the adhesion metal layer under the bottom electrode, the sidewall of the barrier layer, and the switching oxide device of the RRAM device. The second spacer may be fabricated, for example, by depositing a second spacer layer and etching the second spacer layer using the same etch mask. In some embodiments, step 645 may be omitted from process 600.

At step 650, the etch mask may be removed after the fabrication of the first spacer and/or the second spacer. The removal process may involve a wet etching or dry etching technique.

At step 655, a second interconnect may be fabricated on the RRAM device. For example, a third dielectric layer of a second low dielectric constant oxide may be fabricated on the second dielectric layer and along the sidewalls of the RRAM device. The second interconnect may then be fabricated by patterning and etching the third dielectric layer to create a via hole and depositing a suitable conductive material in the via hole.

FIG. 7 is a flowchart illustrating an example process 700 for fabricating a switching oxide device in accordance with some embodiments of the present disclosure.

At block 710, an interface layer B (ILB) may be fabricated. Fabricating the ILB may involve depositing a first interface material that is more chemically stable than the transition metal oxide(s) in the switching oxide layer as described below. In some embodiments, the first interface material may include Al₂O₃, MgO, Y₂O₃, La₂O₃, etc. In one implementation, fabricating the ILB may involve depositing a continuous layer of the first interface material. In another implementation, fabricating the ILB may involve depositing a layer of the first interface material having a suitable thickness to form the first discontinuous film. For example, fabricating the ILB may involve depositing the first interface material to a thickness between about 0.2 nm and about 1 nm. The first discontinuous film may be deposited utilizing PVD, CVD, ALD, and/or any other suitable deposition technique.

At block 720, a switching oxide layer may be fabricated on the interface layer B. The switching oxide layer may include one or more transition metal oxides. The transition metal oxides may include, for example, TaOₓ, HfOₓ, TiOₓ, NbOₓ, ZrOₓ, etc. In some embodiments, during the fabrication of the switching oxide layer, one or more portions of the transition metal oxides may be deposited on the bottom electrode through one or more of the first pores, where ILB is a noncontinuous film. The switching oxide layer may be deposited utilizing PVD, CVD, ALD, and/or any other suitable deposition technique.

At block 730, an interface layer A (ILA) may be fabricated on the switching oxide layer. Fabricating the ILA may involve depositing a second interface material on the switching oxide layer. The second interface material may be more chemically stable than the transition metal oxide(s) in the switching oxide layer. In some embodiments, the second interface material may include Al₂O₃, MgO, Y₂O₃, La₂O₃, etc. In one implementation, fabricating the ILA may involve depositing a continuous layer of the second interface material. In another implementation, fabricating the ILA may involve depositing a layer of the second interface material having a suitable thickness to form a discontinuous film. The ILA may be deposited utilizing PVD, CVD, ALD, and/or any other suitable deposition techniques.

In some embodiments, block 710 or block 730 may be omitted from process 700 to fabricate a switching oxide layer with a single interface layer (e.g., switching oxide device 500a of FIG. 5A or 500c of FIG. 5C).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A semiconductor device, comprising:
an RRAM device, comprising:
a bottom electrode;
a switching oxide device comprising at least one transition metal oxide;
a via structure fabricated on the switching oxide device, wherein the via structure comprises a via fabricated in a hard mask layer; and
a top electrode fabricated within the via structure and over a top surface of via structure.

2. The semiconductor device of claim 1, further comprising a first spacer encapsulating the top electrode and the hard mask layer comprising the via structure.

3. The semiconductor device of claim 2, further comprising a second spacer encapsulating the first spacer and the bottom electrode.

4. The semiconductor device of claim 3, wherein the second spacer further encapsulates the switching oxide device.

5. The semiconductor device of claim 2, wherein the switching oxide device comprises a layer of the transition metal oxide and a first interface layer comprising a first interface material that is more chemically stable than the at least one transition metal oxide.

6. The semiconductor device of claim 5, wherein the switching oxide device further comprises a second interface layer comprising a second interface material that is more chemically stable than the at least one transition metal oxide.

7. The semiconductor device of claim 6, wherein the first interface layer is positioned between the layer of the transition metal oxide and the bottom electrode, and wherein the first interface layer is positioned between the layer of the transition metal oxide and the top electrode.

8. The semiconductor device of claim 5, wherein the first interface layer is positioned between the layer of the transition metal oxide and the top electrode.

9. The semiconductor device of claim 5, wherein the first interface material comprises at least one of Al₂O₃, MgO, Y₂O₃, or La₂O₃.

10. The semiconductor device of claim 1, further comprising:
a first interconnect, wherein the RRAM device is fabricated on the first interconnect; and
a second interconnect fabricated on the top electrode.

11. The semiconductor device of claim 10, further comprising a conductive via fabricated on the first interconnect, wherein the bottom electrode is fabricated on the conductive via.

12. The semiconductor device of claim 1, wherein the top electrode comprises a layer comprising at least one of titanium or tantalum.

13. A method for fabricating an RRAM device, comprising:
fabricating a switching oxide device on a bottom electrode layer;
fabricating a device stack on the switching oxide device, the device stack comprising a via structure fabricated on the switching oxide device and a top electrode layer fabricated within and over the via structure;
etching the device stack; and
fabricating a first spacer along sidewalls of the etched device stack.

14. The method of claim 13, further comprising:
fabricating an etch mask on the top electrode layer prior to the etching of the device stack;
etching, using the etching mask, the switching oxide device to fabricate a switching layer of the RRAM device; and
etching, using the etching mask, the bottom electrode layer to fabricate a bottom electrode of the RRAM device, wherein etching the device stack comprises etching, using the etching mask, the top electrode layer and a hard mask layer using the etching mask, wherein the via structure comprises a via fabricated in the hard mask layer.

15. The method of claim 14, further comprising fabricating a second spacer along sidewalls of the first spacer and the RRAM device.

16. The method of claim 14, further comprising fabricating a conductive via on a first interconnect in a first lithography process using a first patterning mask, wherein the bottom electrode layer is fabricated on the conductive via.

17. The method of claim 16, wherein the via structure is fabricated in a second lithography process using the first patterning mask.

18. The method of claim 16, wherein the via structure is fabricated in a second lithography process using a second patterning mask.

19. The method of claim 18, wherein the second patterning mask is smaller than the first patterning mask.

20. The method of claim 16, further comprising fabricating a second interconnect on the top electrode of the RRAM device.
